(19) United States
(12) Patent Application Publication
(10) Pub. No.: US 2002/0187280 A1
(43) Pub. Date: Dec. 12, 2002

(54) Method and system for reducing damage to substrates during plasma processing with a resonator source

(75) Inventors: Wayne L. Johnson, Phoenix, AZ (US); Murray D. Sirkis, Tempe, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TOKYO ELECTRON LIMITED, Tokyo (JP)

(21) Appl. No.: 10/175,806

(22) Filed: Jun. 21, 2002

Related U.S. Application Data
(63) Continuation-in-part of application No. PCT/US00/33281, filed on Dec. 20, 2000.
(60) Provisional application No. 60/171,512, filed on Dec. 22, 1999.

(51) Int. Cl. C23F 1/00; C03C 25/68; C23C 16/00; H01L 21/469; H01L 21/31

(52) U.S. Cl. 427/569; 118/723 I; 156/345.48; 216/68; 438/710; 438/788

(57) ABSTRACT

A method and system for reducing damage to substrates (e.g., wafers) during plasma processing by using a high pressure source. A thin electrostatic shield enables a large number of thin slots to be formed in an electrostatic shield while still being able to excite the plasma. The bottom of the slots and the top of the substrate are separated such that the mean free path of the plasma particles is between 0.5% and 2% of the distance between the bottom of the slots and the substrate holder.

### CROSS REFERENCE TO RELATED APPLICATIONS

This application is a continuation-in-part of International Application No. PCT/US00133281 filed Dec. 20, 2000, which claims priority to application Serial No. 60/171,512, filed Dec. 22, 1999. The contents of those applications are incorporated herein by reference.

### BACKGROUND OF THE INVENTION

1. Field of the Invention

The present invention is directed to a method and system for reducing damage to substrates (e.g., wafers) during plasma processing, and more specifically to a method and system for reducing the damage by using high-pressure processes.

2. Description of the Background

Known plasma processing systems are used for resist removal, etching, deposition, and other processing steps. For such applications, the processing system contains a “plasma” that is an electrically quasi-neutral ionized gas that typically contains a significant density of neutral atoms, positive ions, negative ions, and free electrons, and in some cases may also contain neutral molecules and metastable atoms, molecules, and ions. Energy must be continuously supplied to the plasma to maintain the level of ionization because the charged particles continually recombine, for the most part within the body of the plasma but also at the walls of the confining chamber. A common source of the requisite power is a radio-frequency (RF) generator with a frequency of 13.56 MHZ, but other frequencies are also used. The relative significance of the two recombination processes depends, in part, on the pressure.

Plasma processing is attractive for many applications because it may be directional (i.e., anisotropic) and, therefore, suitable for use in the manufacture of the densely packed, submicron-scale structures common in present-day semiconductor integrated circuits. The capability to process anisotropically permits the production of integrated circuit features at precisely defined locations with sidewalls that are essentially perpendicular to the surface of a masked underlying surface. In anisotropic plasma processing, the pressure in the processing chamber must be low enough to assure that the mean free path between collisions for the ions is much greater than the sheath dimension. Typical pressures for anisotropic plasma processing lie in the range from <1 mTorr to 50 mTorr. The corresponding mean free paths for argon ions (which are often used) are in the range from about >80 mm to about 1.6 mm.

In a physical enclosure like a processing chamber, the plasma includes two distinct regions. The interior of the plasma, the so-called plasma body, is a quasi-neutral electrically conducting region and is essentially an equi-potential region, i.e., a field-free region. Near the chamber wall, the RF power provided to the reactor chamber couples energy to the free electrons in the plasma, providing many of them with energy sufficient to produce ions when the electrons collide with atoms or molecules in the gas. (Due to the well-known skin effect, the RF field is appreciable only in a region close to the chamber wall.) In addition to this ionization, excitation of atoms and excitation and dissociation of molecules may occur in the plasma body. For example, in excitation, an oxygen molecule may remain a molecule, but absorbs enough energy to be raised to an excited molecular state (i.e., it is no longer in the ground molecular state). In dissociation, an oxygen molecule, O₂, may be split into two neutral oxygen atoms. The relative rates at which those processes occur are related principally to the chamber pressure, the gas composition, and the power and frequency of the RF energy supplied.

Between the plasma body and any adjacent material surfaces, there is a boundary layer, the so-called “plasma sheath.” The plasma sheath is an electron deficient, poorly conducting region in which the electric field strength normal to the sheath surface is large. The electric field in the plasma sheath is essentially perpendicular to the surface of any material object. Examples include the chamber walls, electrodes, and wafers being processed in the chamber if they are immersed in the plasma.

As a result of the electric field in the sheath between the plasma body and an adjacent wafer, ions that enter the plasma sheath from the plasma body are accelerated and impinge on the wafer with a velocity that is essentially perpendicular to the wafer surface, provided that the pressure is so low that the impinging ion undergoes no collisions while passing through the sheath. This perpendicular bombardment makes anisotropic etching possible.

At sufficiently high pressures, however, an ion is likely to collide with other ions or neutrals while passing through the sheath. As a consequence, its velocity will not, in general, be perpendicular to the wafer surface when it strikes the surface and anisotropic processing does not occur.

Many integrated circuit (IC) structures, especially those with very small features, may be damaged if they are bombarded by electrons with sufficiently high energies (greater than a few tens of eV). Oxide gate insulators are especially susceptible to damage caused by electrostatic fields due to high energy electrons. In addition, the plasma emits ultraviolet light, which is also known to damage oxide gate insulators. Consequently, the use of plasma processing to fabricate such circuits is a practical possibility only if the design of the plasma processing equipment addresses these damage mechanisms and permits acceptable process yields with acceptable process throughputs.

Gate oxide damage may be decreased by decreasing the sheath voltage in order to reduce the electron bombardment energy. A lower sheath voltage also reduces ion bombardment damage. With a capacitively-coupled plasma reactor, the sheath voltage can be reduced if the RF power supplied to the plasma chamber is reduced. Regrettably, such a reduction reduces the creation rate of the reactive constituents in the plasma body. Etch rates depend on both the ion current density and the sheath voltage at the wafer surface. When the sheath voltage is reduced (to decrease damage), the ion current density must be increased to maintain an essentially constant etch rate (throughput). The ion current density can only be increased, however, if the RF power delivered to the process chamber is increased. This necessarily results in an increase in the sheath voltage. There is, therefore, a fundamental incompatibility between the requirements of a practical process and a capacitively-coupled reactor.

On the other hand, inductively-coupled electrostatically shielded radio-frequency (ESRF) plasma reactors permit essentially independent control of the sheath voltage and, thereby, the electron energies, as well as the creation rate of the reactive constituents in the plasma body. In a typical ESRF plasma source, the RF power applied to the plasma by means of the induction coil determines the creation rate of the reactive constituents in the plasma body. The RF voltage applied to the driven electrode on which the wafer(s) rest determines the sheath voltage at the wafer(s), and is independent of the energy delivered to the plasma.

For both capacitively-coupled and inductively-coupled plasma reactors, immersion of the wafers directly in the plasma will cause a high particle current density of charged particles from the body of the plasma, through the plasma sheath, and to the wafer surface. In addition to sputtering damage from this ion bombardment, wafers may also sustain damage from exposure to UV radiation, and electrostatic charging. Exposed gate oxides, which are especially vulnerable, may be damaged by direct electron impact if the electron has sufficient energy to bury itself into the oxide and become a trapped charge. Furthermore, as a consequence of the “antenna effect,” the oxide in gates that have been connected to other circuit elements by means of metallic interconnects, may be damaged through charge collection by the interconnecting elements. An ineffective electrostatic shield in a plasma source may also be a cause of gate damage.

In a typical ESRF plasma reactor, the plasma is generated in a region for which the boundaries are determined by the walls of the reactor chamber and the lesser of (1) the length of the exciting inductor, typically a helical coil wound around a slotted, cylindrical, electrically conducting shield that encloses the reactor chamber, and (2) the length of the axial slots in the shield. In an ESRF plasma reactor, only that part of the coil adjacent to the slots in the shield couples effectively to the plasma. In practice, the length of the inductor may be less than or greater than the length of the slots in the RF shield. In such a case, the concentration of the reactive constituents in the plasma body generally depends significantly on position along the axis of the structure, either beyond the coil ends, if the coil length is less than the slot length, or beyond the slot ends, if the slot length is less than the coil length. Consequently, the resulting axial gradient of the reactive constituents in the plasma will give rise to a diffusion particle current density that is axially directed away from the end planes of the inductor or the plane defined by the slot ends.

Techniques have been developed to permit plasma processing techniques to be used for process steps that are extremely sensitive to electron energies. One of these techniques is remote plasma processing, a processing technique in which a wafer being processed is not located in the same region in which the plasma body and plasma sheath are located and is not, therefore, exposed directly to the plasma. In remote plasma processing, the intent is to use this particle diffusion current described in the immediately preceding paragraph to accomplish the desired process step.

In a known remote plasma processor, the plasma source has a small diameter and the reactive constituents from the plasma are transported as far as practically possible from the source to the wafer(s). The path from the plasma to the wafers may include sharp turns to increase the collision of ions with the chamber walls and their neutralization or removal from the stream, and to prevent a direct line-of-sight path between the plasma source and the wafer(s). Typically the plasma is piped through specially coated conduits, such as conduits made from Teflon or alumina.

The intent is thereby to eliminate the exposure of the wafer(s) to ultraviolet radiation and to bombardment by energetic electrons and ions. In general, the distance between the plasma source and the substrate can be very large, i.e. ten times the plasma source diameter. Nevertheless, this approach has disadvantages. First, a complex enclosure may be necessary. Second, the concentration of active constituents; e.g., reactive atoms normally a part of an radical like atomic oxygen, and metastable atoms and molecules will be reduced due to recombination and relaxation that will occur before such constituents reach the wafer.

Known patent references that are related to the present invention include: U.S. Pat. No. 4,918,031, to Flamm et al., entitled “Processes Depending On Plasma Generation Using A Helical Resonator”; U.S. Pat. No. 5,811,022, to Savas et al., entitled “Inductive Plasma Reactor” (FIGS. 1-3 of the present application are taken therefrom); and U.S. Pat. No. 5,234,529 (hereinafter “the '529 patent”), to Johnson, entitled “Plasma Generating Apparatus Employing Capacitive Shielding And Process For Using Such Apparatus.” A portion of FIG. 4 herein is taken from the '529 patent.

Non-patent literature that is related to the present invention includes: Colonell, J. I. et al., Evaluation and reduction of plasma damage in a high-density, inductively coupled metal etcher, Proceedings of the 1997 Second International Symposium on Plasma Process Induced Damage (May 13-14, 1997 at Monterey, Calif.) pp. 229-32, American Vacuum Society; Haldeman, C. W., et al., U.S. Air Force Research Laboratory Technical Research Report, 69-0148, Accession No. TL501.M41, A25 No. 156; MacAlpine, W. W. et al., Coaxial resonators with helical inner conductor, Proc. IRE, Vol. 47, 2099-2105 (1959); Tatsumi, et al., Radiation damage of SiO2 surface induced by vacuum ultraviolet photons of high-density plasma, Japanese J. Appld. Physics, Vol. 33, Pt. 1, No. 4B, 2175-2178 (1944); Turban, Guy, Étude de la temperature et de la densité électroniques d'une décharge H.F. dans l'hydrogène, par la méthode de la sonde double symétrique, C. R. Acad. Sc. Paris, t. 273, Série B, 533-6 (Sep. 27, 1971); and Turban, Guy, Mésure de la fonction de distribution en énergie des electrons d'une décharge H. F. dans l'hydrogène, par la méthode de la sonde triple asymétrique, C. R. Acad. Sc. Paris, t. 273, Série B, 584-7 (Oct. 4, 1971).

Metastable molecules and molecular ions in the most commonly used discharges supply energy essential to cause chemical reactions to occur at the surface and rarely cause damage problems due to their low stored or recombination energies. The energies of metastable atoms and molecules are species dependent and only those of the rare gas metastable atoms have energy sufficient to cause damage. The presence of the lower energy metastable species is, indeed, required.

For example, from ozone (O₃) produced in the plasma, it is possible to generate O⁺, O₂⁺ and various negative oxygen-related ions. Negative ions can be stripped of their extra electrons quite easily and are not likely to be the source of the observed damage. Positive ions can recombine providing at most a few eV of energy depending upon species. Both positive and negative molecular ions are easily neutralized upon collision with walls. And, the wall material may be chosen to have different recombination rates for different species. It is most desirable that positive and negative molecular ions arrive at the substrate surface in essentially equal number thereby preventing the substrate from becoming charged while still activating the surface chemistry. On the other hand, a non-neutral flow of ions to the substrate surface will be limited by their kinetic energies, which are determined partially by charge exchange processes in the plasma and the flow velocity.

### SUMMARY OF THE INVENTION

It is an object of the present invention to reduce the amount of damage to substrates (e.g., wafers or LCDs) that occurs during plasma processing.

These and other objects of the present invention are achieved through the use of a high pressure plasma source that has a well-defined recombination region. By causing the atomic ions and electrons of the plasma to complete recombination before reaching the substrate, and by having a space between the region where the plasma is undergoing ionizing reactions and recombination the UV radiation that might otherwise damage the substrate is substantially absorbed prior to interaction with the substrate. Moreover, by using a large source over a small wafer, edge effects are reduced as well.

The design of the ESRF plasma processor according to the present invention is motivated by the belief that most, if not all of the damage to wafers and bare gate oxides is incorrectly attributed to ultraviolet radiation. It is known that ultraviolet radiation can cause damage at a Si—SiO₂ interface if the photon energy exceeds the SiO₂ bandgap of 8.8 eV, which corresponds to a wavelength of approximately 140 nanometers. In addition, UV photons with much lower energies can produce free electrons that become trapped in the oxide layer and cause undesirable displacements of the capacitance vs. voltage (CV) characteristic of gate capacitors.

It is likely that radiation with wavelengths less than or equal to 200 nm would be virtually completely absorbed in traversing a path length on the order of 1 cm at a pressure of 2 Torr by a process called resonant absorption. Experience with downstream processing equipment using an inductively coupled high-density plasma source with a diameter of 10 cm have confirmed that even when wafers are placed as far as 1 meter from the plasma some damage still occurs. Therefore, it is likely that damage usually attributed to ultraviolet radiation is, in fact, caused by energetic ion or metastable bombardment, and that the effective absorption of all relevant vacuum UV in distances on the order of 5 to 2 cm at pressures in the range from 0.5 Torr to 1.5 Torr is possible, respectively.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a schematic illustration of a known ESRF source;

FIG. 2 is a schematic illustration of a known cylindrical shaped ESRF source;

FIG. 3 is a schematic illustration of a known slot pattern for use in an electrostatic shield of an ESRF source;

FIG. 4 is an illustration of a plasma reaction vessel for use in the present invention;

FIG. 5 is a perspective cutaway view of a cylindrical shaped ESRF source for use in the present invention;

FIG. 6 is a side view of a slot pattern for use in an electrostatic shield of an ESRF source according to the present invention; and

FIG. 7 is a top view of the electrostatic shield shown in FIG. 6 for use in an ESRF source according to the present invention.

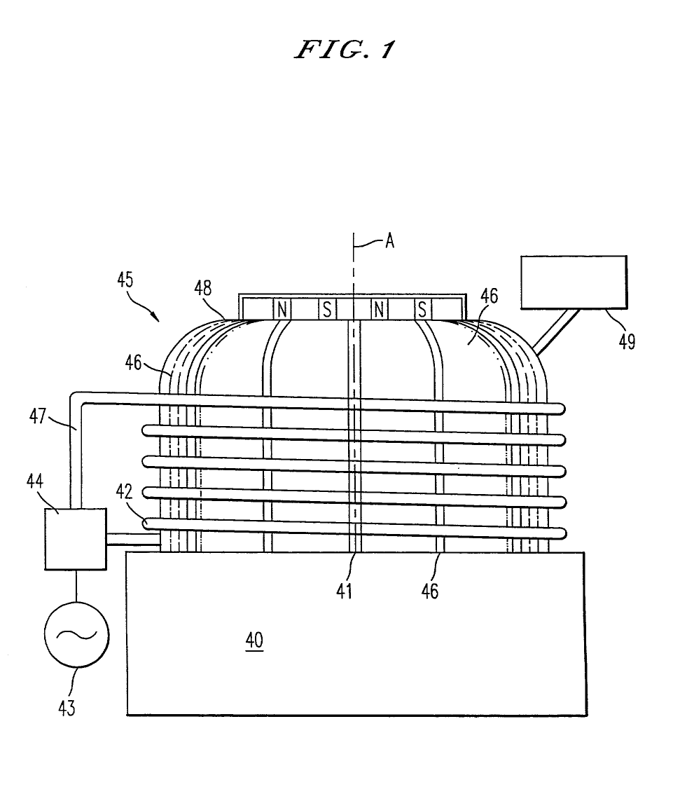

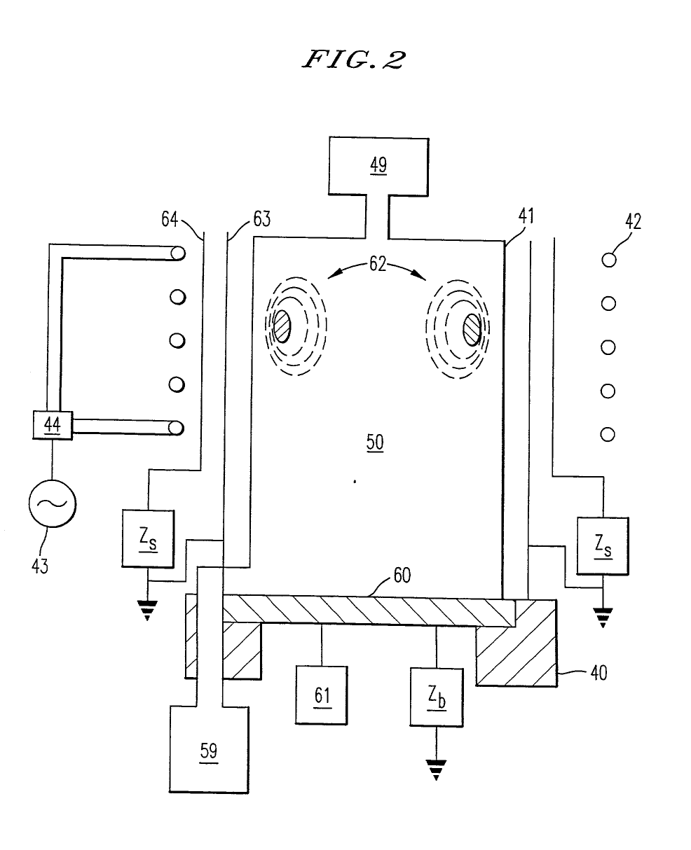

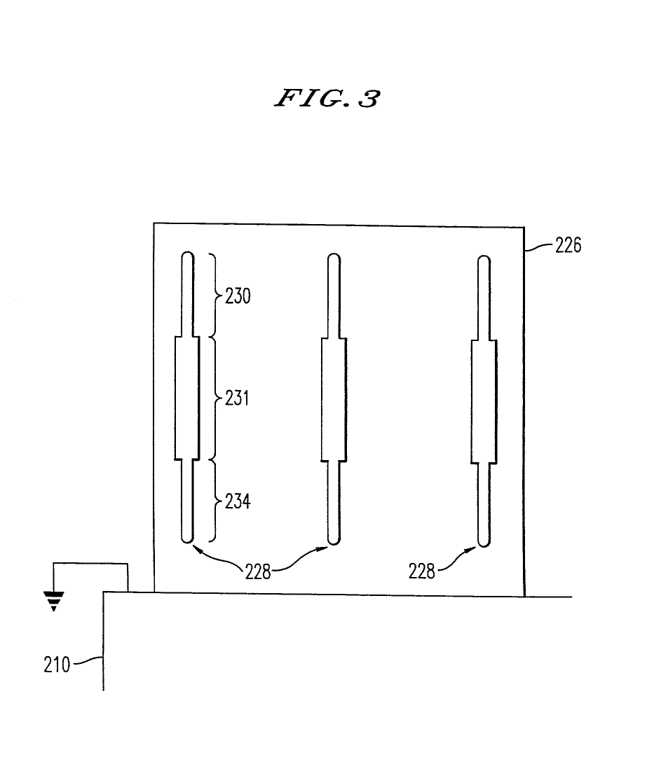

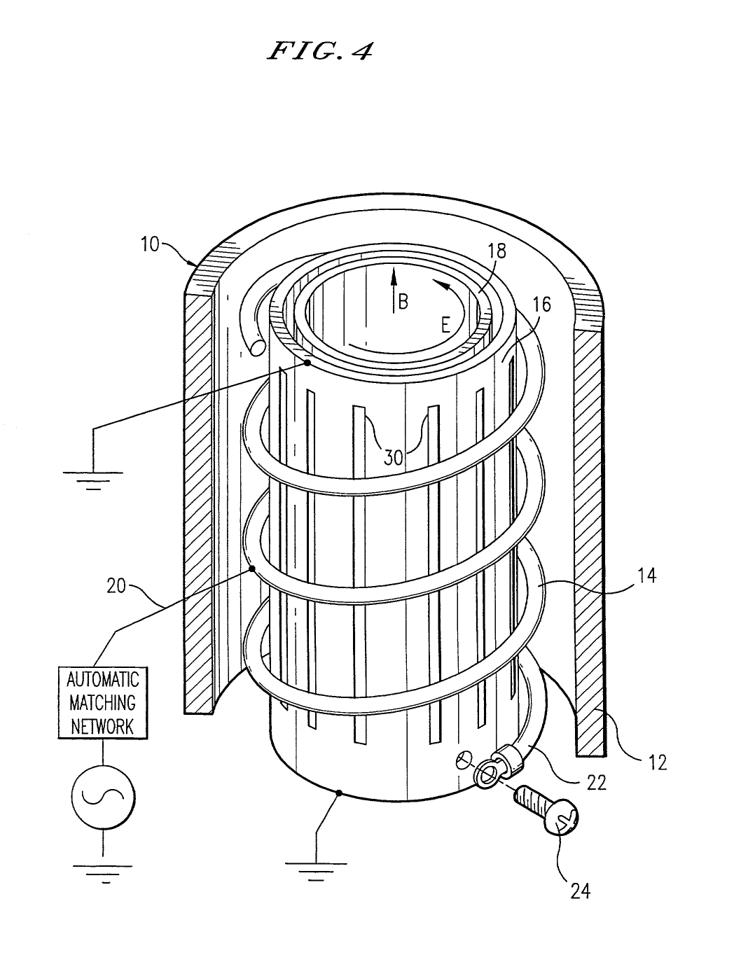

### DETAILED DESCRIPTION OF THE PREFERRED EMBODIMENTS

The atomic ions and electrons are neutralized in the afterglow in the absence of the active plasma in times on the order of a microsecond. However, it is less likely that the positive and negative molecular ions will be neutralized quickly in the gas phase in the absence of free electrons at the pressures of the present invention because energy and momentum cannot both be conserved in a two-body coalescing collision between an electron and a much more massive positive ion. A third species that of metastable are both atomic and molecular in size and may be ionic either positive or negative in charge. This species is specified in that it cannot reduce it's electronic state without at three body collision. A third body (e.g., a surface or a second atom or molecule) is necessary to conserve the energy liberated during the neutralization of a metastable. Therefore, at the pressures of the present invention, the formation of these metastables typically occurs by means of collisions in the plasma afterglow, just downstream from the active plasma. It is important to recognize that the greater the distance between the active plasma and the substrate, the less the chemical activity that can be produced at the substrate. Most metastables provide useful non-damaging energy for the chemical process but rare gas metastables have sufficient energy to damage the substrate.

The flow pattern in this downstream processing system is believed to be essentially laminar, which permits the partitioning of the flow along flow lines. One feature of this flow segregation is that the positive and negative molecular ions are emitted from the recombination regions in equal numbers. This eliminates any charging of the substrate surface by differential molecular ion flow.

In one embodiment of the present invention, a twelve-inch diameter chamber is used to process an eight-inch diameter wafer. Molecular ions that flow past a surface, some impact that surface and because of a net difference in the charge neutralization rate for different species a net charge appears in the flow close to surfaces. It is believed that any net charged ion flow generated at or near the walls of the large-diameter source are swept past the wafer through the annular region between the edge of the wafer and the inner dielectric wall of the plasma source and, therefore, do not strike the wafer. Langmuir probe measurements of electron and ion concentrations near the surface of a four-inch-diameter wafer located four inches from a twelve-inch-diameter plasma source showed no detectable charged species. The technique was capable of detecting net charge concentrations of charged species as low as 10⁹ per cm³.

In the system of the present invention, wafers to be processed are placed approximately below the plane determined by the lower slot ends by a distance required by to absorb the UV radiation from the plasma. Absorption of the vacuum ultraviolet radiation in the region between the boundary layer and the wafers is sufficiently great to reduce radiation damage of bare gate oxides to acceptable levels. If UV damage is observed in any especially sensitive procedure, a modest increase in the distance between the active plasma and the substrate will reduce it to an acceptable level.

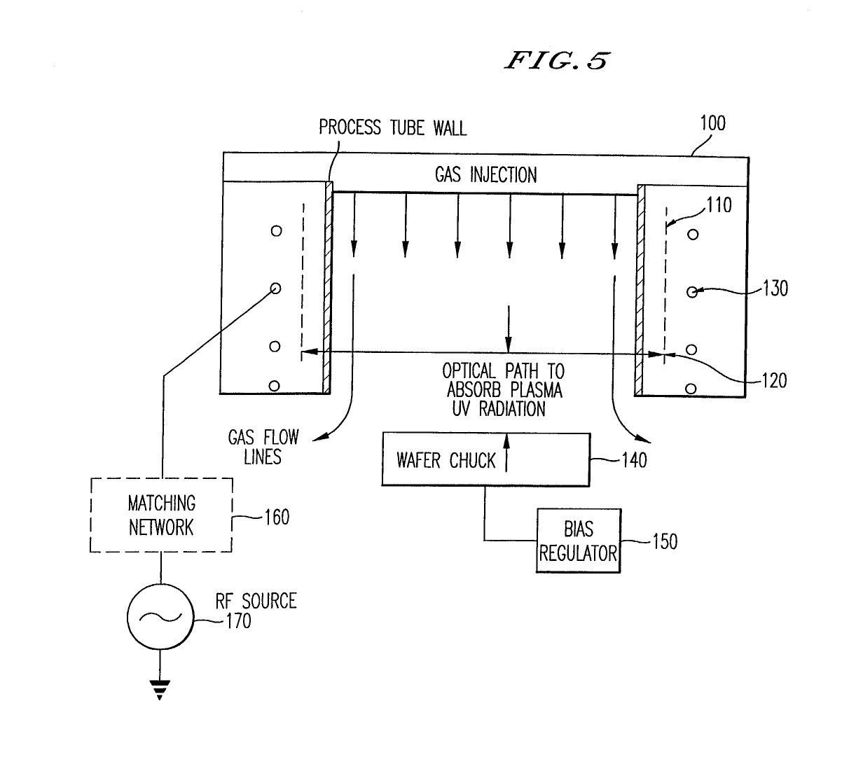

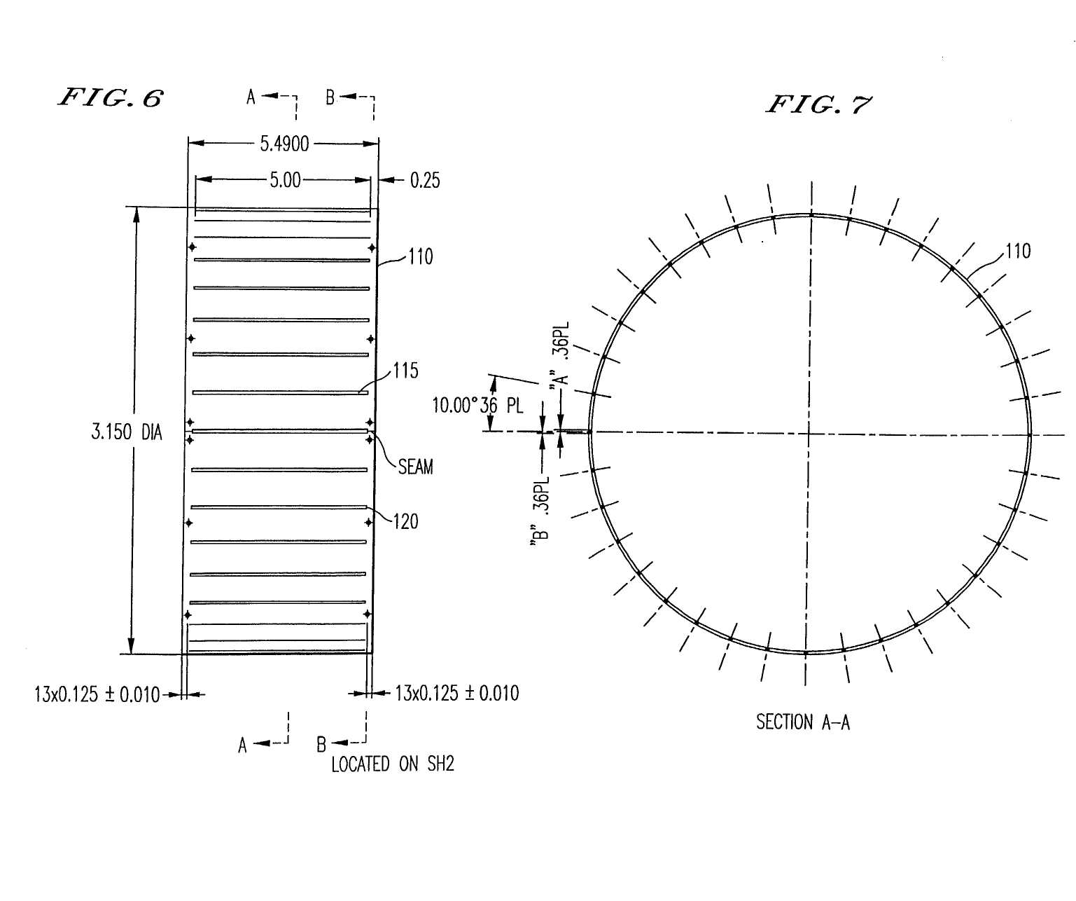

Turning now to the drawings in which like reference numerals designate identical or corresponding parts throughout the several views. FIGS. 5-7 illustrate a plasma reaction vessel enclosing processing chamber, allowing a vacuum to be established in the processing chamber. A vacuum pumping assembly (not shown) provides the necessary processing vacuum. Notably, the present invention utilizes pressures in the range of approximately 0.5 to 1.5 torr. A gas inlet manifold 105 allows for the introduction of the appropriate process gasses. Ideally, the process gasses will be chosen to ensure simple gas chemistry. Additive gasses, especially rare gasses, are avoided since they can increase the amount of UV radiation generated by the plasma.

The system includes an electrostatic shield 110. Grounding contacts (not shown) ensure proper grounding of the electrostatic shield. A well-grounded shield provides a greatly reduced capacitive coupling to the plasma at less than 25 millivolts RMS. Numerous slots 115 are provided in the electrostatic shield. The number of slots 115 may range from 5 to more than 48, with 36 being preferred in the present system. The slots 115 are of uniform width, with the possible range of widths being from 0.015 inch to 0.50 inch, with 0.063 inch being preferred. The shield 110 is fabricated from sheet aluminum between 0.015 inch to 0.2 inch thick, with approximately 0.063 inches thick being preferred. After rolling and seaming, its height is between 4.0 inches and 7 inches, with approximately 5.5 inches being preferred, and its diameter is between 8 inches and 20 inches, with approximately 13.15 inches being preferred. The diameter of the chamber determined by the electrostatic shield 110 is significantly greater than the wafer diameter. For example, a chamber with a diameter of twelve inches is appropriate for processing a wafer with a diameter of eight inches. In one illustrative embodiment, the shield 110 is silver-plated to increase conductivity. Other coatings are possible, and the shield is alternatively not coated. Moreover, the shield may be made of alternate metals.

The slots 115 terminate at a distance between 0.125 and 0.5 inches from each end of the shield 110, with approximately 0.25 inch being preferred. The slot 115 length is between 2.5 and 7.5 inches, with approximately 5.00 inches being preferred. Alternative embodiments are also possible in which any of the above parameters are varied including these where the slots are taller than in the source is in diameter.

The RF coil 130 is wound around the electrostatic shield 110 but only makes contact with the shield 110 at one end where the RF ground is provided. The RF coil 130 extends above and below the ends 120 of the slots 115. In an ESRF plasma reactor, only that part of the coil 130 adjacent to the slots 115 in the shield 110 couples effectively to the plasma. In practice, the length of the inductor 130 may be less than or greater than the length of the slots 115 in the electrostatic shield 110. In such a case, the reactive constituents in the plasma body generally depend significantly on position along the axis of the structure, either beyond the coil 130 ends, if the coil 130 length is less than the slot 115 length, or beyond the slot ends 120, if the slot 115 length is less than the coil 130 length. In the preferred embodiment, the coil 130 is longer than the slots 115, so that the active plasma extent is determined by the slot ends 120.

Both the coil 130 and the electrostatic shield 115 are enclosed in the coaxial electrically conductive enclosure. The coil 130, shield 115 and enclosure create a low-loss electrical helical resonator that is resonant at the operating frequency of 13.56 MHZ. This arrangement permits the resonant circuit to have a quality factor (Q), prior to plasma ignition, on the order of 1000. For a given available power, the effect of a high Q is to increase the electric field intensity available to ignite the plasma on the order of the square root of Q. The RF source 170 is connected to a suitably located tap 131 on the coil 130 through an automatic matching network 160. The absorption of RF energy by the plasma causes the Q to decrease, and the electric field near the slots becomes small enough to preclude the production of charged particles with energies in excess of about 10 eV. The well defined lower boundary layer between the plasma and the virtually plasma-free region has a thickness on the order of 1 mm at a pressure of approximately 1 torr. The present invention utilizes the general rule that the recombination distance (i.e., the distance in which the free electrons and ions disappear) should be short compared to the distance to the wafer. However, the absolute distance between the bottom of the slots 115 of the e-shield 110 and the wafer chuck 140 is a function of the pressure inside the ERSF source 100. The high-pressure limit of the present invention is only limited by the ability of the system to excite a plasma in the source 100 and the uniformity of that excitation. The low-pressure limit of the present invention is limited by the fact that the mean free path of the plasma particles should be between 0.5% and 2% of the distance between the bottom 120 of the slots 115 and the substrate on the wafer chuck 140 (that optionally includes a temperature control device, e.g. a heater). In a preferred embodiment, the mean free path of the plasma particles is 1% of the distance between the bottom 120 of the slots 115 and the substrate. As would be appreciated by one of ordinary skill in the art, other separation distances are possible. The design of the wafer chuck and the vacuum system are such that energetic ions entrained in the gas flow and passing though the annular region between the wafer edges and the chamber walls do not strike the wafer.

The thickness of the shield is determined by two considerations: (1) If the shield is too thick, the Q of the resonant circuit in which it is a component will be degraded; and (2) If the shield is too thin, it will be structurally weak. The slot width is also determined by two considerations: (1) If the slots are too narrow, ignition of the plasma is practically too difficult to achieve; and (2) If the slots are too wide, charged particles, both electrons and ions, acquire too much energy through acceleration by the capacitively coupled electric field near the slots. Consequently, the electron bombardment of the substrate become great enough to cause wafer damage, especially to bare gate oxides during etch processes. The azimuthal uniformity of the plasma increases with the number of slots, but the capacitive shielding decreases with increasing slot width. These considerations establish a practical lower bound on the number of slots and an upper bound on the slot width.

When special care must be taken to prevent damage to wafers or to circuit structures -on wafers, (e.g., near the end of material removal or etch procedures), the sheath voltage must not be allowed to become too large as compared to the breakdown voltage of any part of the wafer circuitry. Consequently, under such circumstances, the substrate holder will usually be unbiased. It is also known that the sheath voltage in an ESRF plasma generator depends on the energy of the electrons at the high-energy end of the electron energy distribution—the so-called “electron energy tail”—and the electron energy tail depends, among other things, on the plasma constituents, the RF power level, and the pressure. The sheath voltage decreases dramatically with increased pressure and becomes very small (e.g., of the order of a volt) for pressures greater than about 0.5 Torr. Therefore, if the pressure is greater than about 0.5 Torr, wafer or circuit damage due to the acceleration of ions through the unbiased sheath is virtually eliminated.

In one embodiment of the present invention, the ESRF source 100 is coupled to an automatic matching network 160. The automatic matching network 160 is used to maintain optimal coupling between the RF source 170 and the plasma as the plasma becomes established and as plasma conditions change. The absorption of RF energy by the plasma causes the Q to decrease, and the electric field near the slots 115 becomes small enough to preclude the production of charged particles with energies in excess of about 10 eV. Thus, the shield 110 is a component of a circuit designed to resonate at the RF drive frequency (e.g., 13.56 MHZ) of the RF source 170.

Accordingly, the present invention is an improvement upon existing designs such as those described in U.S. Pat. Nos. 5,811,022, 5,234,529, and 4,918,031, discussed above. Obviously, numerous modifications and variations of the present invention are possible in light of the above teachings. It is therefore to be understood that, within the scope of the appended claims, the invention may be practiced otherwise than as specifically described herein.

1. A plasma processing apparatus comprising:
a high pressure gas injection system;
an induction coil for applying RF power to the plasma processing apparatus;
an electrostatic shield for blocking a portion of the RF power applied by the induction coil, wherein the electrostatic shield comprises a number of slots; and
a substrate holder positioned below the electrostatic shield such that the mean free path of the plasma particles is between 0.5% and 2% of the distance between the bottom of the slots and the substrate holder.

2. The plasma processing system according to claim 1, wherein the number of slots is between 24 and 48.

3. The plasma processing system according to claim 2, wherein the number of slots is 36.

4. The plasma processing system according to claim 1, wherein a width of the slots is between 0.015 in. and 0.50 in.

5. The plasma processing system according to claim 4, wherein a width of the slots is 0.063 in.

6. The plasma processing system according to claim 1, wherein a thickness of the electrostatic shield is between 0.01 in. and 0.2 in.

7. The plasma processing system according to claim 6, wherein a thickness of the electrostatic shield is 0.06 in.

8. The plasma processing system according to claim 1, wherein the Q value is between 500 and 2000.

9. The plasma processing system according to claim 8, wherein the Q value is approximately 1000.

10. The plasma processing system according to claim 1, wherein the pressure inside the plasma processing system is between 0.25 Torr and 4.0 Torr.

11. The plasma processing system according to claim 1, wherein the pressure inside the plasma processing system is between 0.5 Torr and 2.0 Torr.

12. The plasma processing system according to claim 1, wherein the pressure inside the plasma processing system is approximately 1.0 Torr.

13. A plasma processing method comprising:
injecting a processing gas into a plasma processing apparatus using a high pressure gas injection system;
applying RF power to the plasma processing apparatus using an induction coil;
positioning a substrate holder below an electrostatic shield having a number of slots such that the mean free path of the plasma particles is between 0.5% and 2% of a distance between a bottom of the slots and the substrate holder; and
blocking a portion of the RF power applied by the induction coil using the electrostatic shield.

14. The plasma processing method according to claim 13, wherein the number of slots is between 24 and 48.

15. The plasma processing method according to claim 14, wherein the number of slots is 36.

16. The plasma processing method according to claim 13, wherein a width of the slots is between 0.015 in. and 0.50 in.

17. The plasma processing method according to claim 16, wherein a width of the slots is 0.063 in.

18. The plasma processing method according to claim 13, wherein a thickness of the electrostatic shield is between 0.01 in. and 0.2 in.

19. The plasma processing method according to claim 18, wherein a thickness of the electrostatic shield is 0.06 in.

20. The plasma processing method according to claim 13, wherein a Q value is between 500 and 2000.

21. The plasma processing method according to claim 20, wherein a Q value is approximately 1000.

22. The plasma processing method according to claim 13, wherein a pressure inside the plasma processing system is between 0.25 Torr and 4.0 Torr.

23. The plasma processing method according to claim 13, wherein a pressure inside the plasma processing system is between 0.5 Torr and 2.0 Torr.

24. The plasma processing method according to claim 13, wherein a pressure inside the plasma processing system is approximately 1.0 Torr.
